(19) United States
(12) Patent Application Publication
(10) Pub. No.: US 2010/0069278 A1
(43) Pub. Date: Mar. 18, 2010

(54) Method for the Production of a Windshield Wiping Concentrate in the Form of Tablets, Windshield Wiping Concentrate, and Corresponding Presentation

(76) Inventor: Natale Licciardi, Remscheid (DE)

Correspondence Address: Scott R. Foster;Pandiscio & Pandiscio, 470 Totten Pond Road, Waltham, MA, 02451-1914, US

(21) Appl. No.: 12/308,825

(22) PCT Filed: Jun. 27, 2007
(86) PCT No.: PCT/EP2007/005658

§ 371 Date: Oct. 2, 2009

(30) Foreign Application Priority Data
Aug. 29, 2006 (DE) 10 2006 040 352.5

(51) Int. Cl. C11D 17/00

(52) U.S. Cl. 510/180

(57) ABSTRACT

The invention relates to a method for producing a windshield wiping concentrate in the form of tablets, said windshield wiping concentrate in the form of tablets, and a corresponding presentation.

The present invention relates to a method for pelleting a windshield washing concentrate in the form of tablets according to the preamble of the main claim, the presentation of pelleted windshield washing concentrates of this type and a windshield washing concentrate in the form of tablets produced in this way.

It is known to add windshield washing concentrates in liquid form to the windshield washer container of a vehicle (see e.g. www.autosol.de).

It is also known to add windshield washing concentrates in the form of tablets to the wash water of a supply container of a motor vehicle.

The articles having the item number 369 579 which can be obtained under www.westfalia.de are tablets of about 8 grams in weight and are intended for approximately 2.5 liters of washing fluid.

The problem is that these tablets are simply too large and heavy. For example, if one wishes to produce about 7 to 10 liters windshield washing concentrate, as e.g. in certain types of vehicles, then three to four tablets of this size are required for this purpose. This corresponds to approximately 24 g-32 g concentrate addition.

Consequently, the object of the invention is to propose a method for the production of windshield washing concentrate in the form of tablets, that leads to a windshield washing concentrate in the form of tablets, which avoids the aforementioned disadvantages.

A further object of the invention is to provide a packaging unit for the tablet form thus produced by means of which the windshield washing concentrate can be easily and accurately measured out and which nevertheless offers the necessary security against manipulation by children.

A further object of the invention is to also give the windshield washing concentrate in the form of tablets according to the invention additional advantages in addition to the purely functional composition in order to increase marketability.

This object and the secondary objects are solved by the features of the patent claims.

The invention results in the advantage that the windshield washing concentrate exists in a form that can be measured very accurately for the amount of water present in each case, whereby the respectively produced tablet size easily fits into the inlet opening of every conventional wash water container.

Therefore, excessively large molded articles do not have to be manipulated to provide the wash water with the cleaning concentrate.

The molded articles can, for example, have a diameter of up to about 15 mm relative to one to three liters washer fluid, with a thickness of about 10 mm. In one embodiment, the tablet, which is measured for about 1 l water, has a volume of about 0.5 cm³.

Thus, these are relatively small, easy-to-handle tablets which can be measured out without difficulty.

The essential aspect of the invention is based on a surfactant constituent of more than 40% relative to the raw material used.

Consequently, up to 16 times as many percent by weight of surfactants are contained as in the aforementioned tablets of the prior art.

In view of the fact that the high surfactant concentration is primarily responsible for the cleaning efficiency, additional cleaning adjuvants, such as phosphates and e.g. trisodium nitrilotriacetate, can be omitted.

The missing phosphates lead to a clearly lower stress on waste water and waste-water purification plants, the latter cleaning adjuvant is even suspected of being carcinogenic.

This advantage is obtained in that the surfactants required for the windshield washing must first be evaporated until they have a dry consistency.

However, the addition of a water-soluble inert substance to the aqueous surfactant solution is of significance in this respect.

This inert substance must be such that it forms a complex with the surfactant without reacting chemically with said surfactant.

This complex can be evaporated to form a dry powder which can then be pressed in association with citric acid and sodium bicarbonate to form tablets.

The water-soluble inert substance which is added to the aqueous surfactant solution thereby forms a molecule-based complex with the surfactants without reacting with them.

In this respect, the term “inert substance” relates to the fact that there is no chemical reaction between the surfactants and the inert substance, but only a complex compound.

In an advantageous embodiment of the invention, the evaporation of this complex is brought about by a process step in which a negative pressure of about up to 40 mbar is produced at a temperature in the order of magnitude of 50-60°.

The water contained in the surfactant solution, which is fed to the vacuum chamber together with the inert substance, evaporates in this vacuum and is drawn off via a corresponding pump.

In this respect, this embodiment of the invention should be differentiated from spray drying which is less suitable for the invention.

That is, in spray drying, a considerable portion of water is left behind, so that this concentrate can not be molded.

Vacuum drying also differs from this insofar because it offers the possibility of keeping the substrate, which consists of the surfactant found in solution and added water-soluble inert substance, continuously in motion in the vacuum container by continuously intermixing using mixing blades, optionally also with cutting blades, in order to in this way produce a homogeneous powdery dry substance which can be easily pelleted.

In contrast to the spray-drying method, a very high surfactant constituent of more than 40% can thereby be obtained. Nevertheless, there is pelleting with this high surfactant constituent.

In this case, the citric acid portion can be up to about 35% by weight.

As all additives are thus water soluble, one also does not require any water-insoluble pelleting adjuvants, such as magnesium stearate, cellulose or explosives.

The tablet according to the invention thereby completely dissolves in water and all conventional alcoholic antifreezes up to 100%.

Sugar is, for example, suitable as a possible inert substance.

Furthermore, due to the water-soluble properties, no antifreeze materials must be introduced into the tablets.

Therefore, the concentrate of the surfactants is pulverized together with the inert substance and, optionally, also with the additives.

The surfactants are originally found in an aqueous solution and are then concentrated accordingly together with the inert substance by evaporation.

The required additives, which are also in a dry consistency form, can be added beforehand or subsequently.

The mixture can also already be easily mixed during drying or also later with conventional means before it is molded in a corresponding pelleting press.

Preferably, the windshield washing concentrate is in the form of tablets which contain no more than 10 g, preferably no more than 5 g, of the mixed dry substrate.

In a further embodiment of the invention, the individual tablets can also have no more than 2 g and should then be used for half the amount of base volume of e.g. 2 liters washing liquid.

The additive sodium bicarbonate together with citric acid dissolves quickly and uniformly in water in an effervescent manner, so that, in spite of a high mold density of the tablets, the entire tablet contents dissolve almost immediately after filling with wash water.

Moreover, sodium bicarbonate together with citric acid also has a certain cleaning capability, so that the surfactants contained as active component are also assisted in their cleaning capability.

In addition, pigments can also be added, preferably pigments which correspond to the main colours of predetermined consumers.

The purpose of this step is to offer for sale to the consumer individually dyed tablets in each case which, due to their coloring—single-coloured or multicoloured—fit in the product image of the respective vendor.

In addition to this, fragrant substances can also be introduced, e.g. perfume oils, in order to also appeal to the purchaser's sense of smell for specific use of said tablets.

Furthermore, with the predetermined method, tablets can also be produced which do not have to be provided with a round cross section. For example, the tablets can have the outer contour of a pilgrim scallop, a diamond, a shield or the like.

The purpose of this step is to also document the Corporate Identity of a specific vendor by the correspondingly contoured tablets.

Moreover, the use of a presentation in the form of a bubble wrap package offers the advantage of childproofing, because children usually can not easily open bubble wrappings of this type.

Of course, without a bubble wrap package of this type, the tablet according to the invention can also reach the market in a tablet tube.

By using a so-called matrix die pair, which is inserted into a corresponding perforated plate on both sides, tablets of this type can be produced with a slippery surface which is especially suitable to also clearly reproduce details of company logos.

The components of the tablet are compressed so strongly by the high pressure applied in a table press of this type that there are no possible points of attack for germs or for moisture absorption on the slippery surface, and that, consequently, the addition of preservatives can be omitted.

Tablets, whose density was about 2.5 g per cubic centimeter, were thereby produced under a corresponding mold pressure.

Tablets of this type were also still easily soluble in water and yet small from the volume point of view with the desired high cleaning efficiency.

Nevertheless, the tablet alone is dissolved as quickly as possible in the wash water by use of sodium bicarbonate with citric acid.

Furthermore, it is recommended that the tablet form be selected so large that it has a sufficient cleaning capability together with a predetermined amount of water, also called base volume, e.g. 2 liters.

Advantageous embodiments can be found in the subclaims.

The invention is described in greater detail in the following with reference to an example of an embodiment.

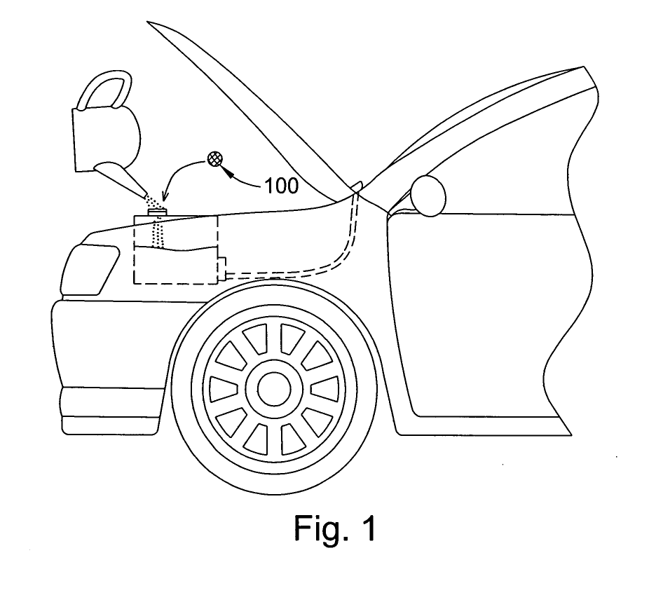

FIG. 1 shows a first embodiment of the invention.

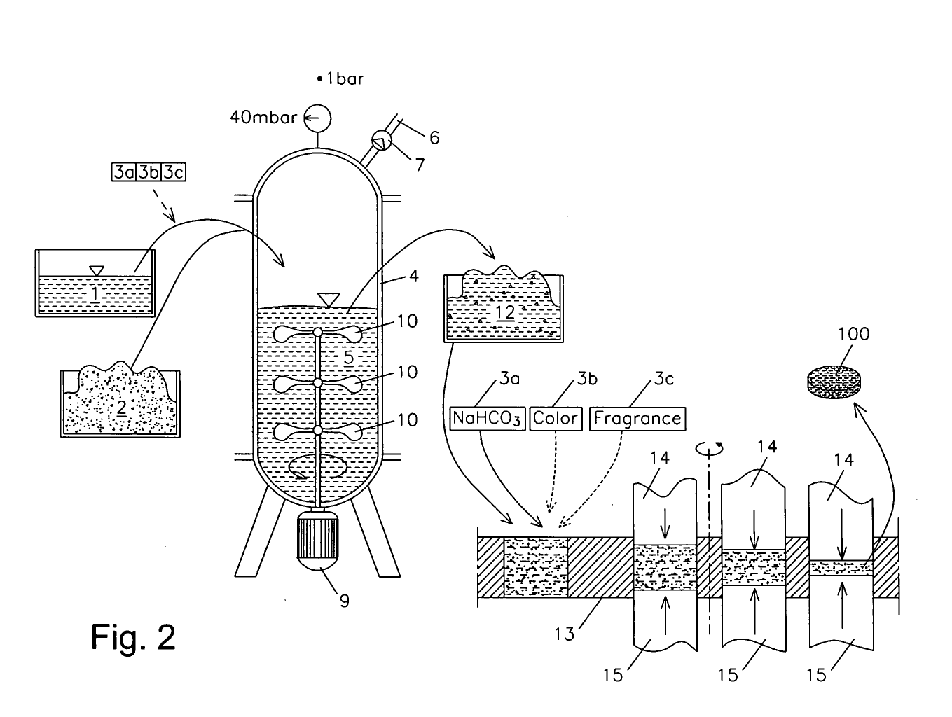

FIG. 2 shows a schematic representation of the method with variants.

Unless otherwise stated in the following, the following description applies to all figures.

The windshield washer container of a motor vehicle is furnished on site with a pelleted form of a windshield washing concentrate according to the invention.

Thereafter or beforehand, the container is filled with normal tap water.

It is important that the windshield washer concentrate is pelleted and consists of a concentrate comprised of evaporated surfactants previously in an aqueous solution which are mixed with an inert substance, e.g. with sugar, so that the dry consistency of the tablet 100 contains an essentially highly concentrated surfactant.

Additives can be added to these surfactants which are in the evaporated concentrate of the original solution, including the inert substance which must be water soluble, said additives preferably having also been in a dry consistency form.

These additives are pulverized together with the evaporated concentrate in a dry consistency form and thoroughly mixed such that a charge of tablets 100 of this type produced has a homogeneous quality.

According to the invention, a tablet 100 of this type should not weigh more than 10 g, preferably not more than 5 g or as ½ a dosage not more than 2 g.

It was shown that tablets 200 could be produced with the present method which are suitable at about 4 g weight for about 1 liter washing fluid, analogously, a tablet 100 of up to about 2 g weight would be suitable for about ½ liter washing fluid.

These correlations are linear and tablets 100 could also be easily used which are provided for up to about 2 to 4 liters washing fluid or e.g. for trucks at 30 cubic centimeters volume for 65 liters of cleaning fluid.

It is also essential that, in addition to the evaporated surfactants 1, sodium bicarbonate be present in order to be able to dissolve the tablet 100 quickly in an effervescent manner in added water.

Citric acid, which has a supplementary cleaning effect together with sodium bicarbonate, can be present as a further additive.

Furthermore, pigments, fragrant substances or also antifreeze additives can be provided to furnish the tablets 100 according to the invention with further functions.

This results in the advantage that the recognition value of such products, e.g. due to the respectively recognizable colour, can be preprogrammed.

Thus, for example, it can be provided that tablets 100 of this type which are red in colour are provided with high concentrations of active substances, those which are green with low concentrations, etc.

Moreover, a tablet 100 of this type can also be furnished in the form of the logo of a specific vendor, vendor chain or the like.

In addition, the arrangement of these tablets 100 in a bubble wrap package is of considerable importance. This step is not only useful for keeping the individual tablets 100 absolutely dry against environmental influences but also for childproofing, as already noted.

Since the tablets 100 preferably contain sodium bicarbonate they are also hydrophilic.

For this reason, the bubble wrapping also presents itself because each individual tablet 100 is then accommodated in a self-contained volume which is protected against ambient moisture.

The tablets 100 shown have a diamter of not more than 20 mm at a thickness of not more than 15 mm.

Depending on conditions, the thickness can also be less than 10 mm at a diameter of less than 15 mm.

If tablets 100 of this type are produced by a matrix die pair known in the prior art, the applied pressures are so high that the surfaces become slippery.

This offers the further advantage that company logos or marks can be easily pressed into the surface by correspondingly contoured matrix dies

The applied pressures that can be produced with matrix die pairs of this type are, in fact, clearly higher than the pressures which can be obtained via allocated press roll pairs.

Moreover, FIG. 2 schematically illustrates the procedural steps for producing the product according to the invention.

A surfactant 1 which is in solution and an inert water-soluble substance 2 are combined.

This mixture can be provided with individual additives 3a, 3b, 3c before or after combining, it being irrelevant, in principle, at what point the additives are added.

However, if the additives are in a liquid state, they must be added prior to drying of the mixture consisting of surfactant 1 and inert substance 2, so that they can also be subjected to the drying process.

This mixture, which consists of a surfactant 1 in solution and inert substance 2, is then placed in a drying container 4, optionally together with the additives 3a-3c, where the surfactant 1 is first evaporated together with the inert substance until it has a dry consistency to form a concentrate 5.

In this respect, it is essential that the drying container 4 have a suction connection 6 via which it can ultimately be evacuated via a suction pump 7.

Taking into consideration an ambient pressure of about 1 bar, it is proposed that it be possible to evacuate the drying container 4 to such an extent that the static pressure present there is less than 0.1 bar, preferably less than 0.05 bar.

It was shown that a process pressure of about 40 mbar can be realized and enables the process to be conducted efficiently.

In addition, it is proposed that the drying container 4 be heated to an internal temperature of about 50-60° C. via a suitable heating device.

In this respect, a process temperature is essential that is above the ambient temperature to aid the evaporation of the liquid in the mixture. Furthermore, a known mixing device is arranged inside the drying container 4 which can be rotary-driven via an electromotor 9 situated outside of the container.

A mixing device 8 of this type has, for example, mixing blades 10 which can, however, also be designed in such a way that the processed mixture is continuously broken down in a pulverizing manner during the evaporation process.

If the additives 3a-3c are in a liquid form, they must be introduced into the drying container 4 prior to filling in the mixture.

If the additives are in powder form, they can be introduced into the drying container 4 prior to inserting the mixture or, optionally, also thereafter.

In any event, the dried intermediate product 12 leaving the drying container 4, which is in a powdery modable substance, can then be further processed in a pelleting machine.

A rotating matrix 13 which has corresponding holes is used for this purpose.

The holes can be brought into aligning positions at those points where the pelleting machine has a matrix die pair 14 and 15 each.

If the holes are filled with the intermediate product 12 to be pressed, then the matrix die pairs 14, 15 are driven toward one another and the intermediate product 12 situated in the holes is compacted to such an extent that a pelleted product is ultimately produced.

However, this method is part of the prior art, so that reference is made to the prior art for all details not mentioned here.

It should thereby also be made clear that the intermediate product 12 is the substance evaporated to the dry consistency to form a concentrate which is ultimately suitable for pelleting, in spite of a surfactant concentration of more than 40% by weight.

### List of Reference Numbers

1 Surfactant

2 Inert substance

3a Additive, NaHCO₃

3b Additive, pigments

3c Additive, others such as fragrance, citric acid

4 Drying container

5 Concentrate

6 Suction connection

7 Suction pump

8 Mixing device

9 Electromotor

10 Mixing blades

12 Intermediate product

13 Matrix

14 Upper matrix die

15 Lower matrix die

100 Tablet

1. A method for pelleting a windshield washing concentrate comprising at least one surfactant (1) in solution and additives (3a, 3b, 3c), at least one of which is an inert water-soluble substance (2), wherein the surfactant (1) is evaporated together with the inert substance (2) to a dry consistency to form a concentrate, and the additives (3a, 3b, 3c) are added selectively subsequently or beforehand, and the pelleting then takes place.

2. The method according to claim 1, wherein the inert substance comprises sugar.

3. The method according to claim 1, wherein the additives (3a, 3b, 3c) are added in their dry consistency state.

4. The method according to claim 1, wherein a concentrate (12) in dry consistency form is pulverized prior to the pelleting and, optionally, mixed with the added additives (3a, 3b, 3c) which are present in a dry consistency form.

5. The method according to any one of the claims 4, wherein not more than 10 g are pelleted from the concentrate (12) to form a tablet (100).

6. The method according to claim 4, wherein not more than 5 g are pelleted from the concentrate (12) to form a tablet (100).

7. The method according to claim 4, wherein not more than 2 g are pelleted from the concentrate to form a tablet (100) each.

8. The method according to claim 1, wherein at least one additive comprises sodium bicarbonate.

9. The method according to claim 8, wherein another additive comprises citric acid.

10. The method according to claim 8, wherein another of the substances comprises a pigment.

11. The method according to claim 1, wherein further additive contains a fragrance.

12. The method according to any one of the claim 2, wherein the surfactant (1), together with the inert substance (2), is evaporated in an atmosphere which has a static pressure of less than 1 bar.

13. The method according to claim 12, wherein the atmosphere has a pressure of less than 0.1 bar.

14. The method according to claim 13, wherein the atmosphere has a pressure of less than 0.05 bar.

15. The method according to claim 1, wherein the surfactant (1) is evaporated together with the inert substance (2) and continuously mixed.

16. The method according to claim 1, wherein the surfactant (1) is evaporated together with the inert substance (2) and continuously broken down in a pulverizing manner.

17. The method according to claim 1, wherein the temperature during evaporation is above the ambient temperature.

18. The method according to claim 17, wherein the temperature is in an order of magnitude of 50 to 60 degrees celsius.

19. The method according to claim 1, wherein the pelleting takes place with predetermined outer contour which is not circular.

20. The method according to claim 1, wherein the pelleting takes place in a matrix (13) which is acted upon on both sides by a matrix die (19, 15) each.

21. The method of a pelleting windshield washing concentrate according to claim 1, wherein a bubble wrap packaging is placed about individual tablets such that the tables are individually packed.

22. A windshield washing concentrate in tablet form produced according to claim 5, wherein the diameter of the tablets (100) is not greater than 20 mm and their thickness not greater than 15 mm and that the tablets (100) contain a concentrate (12) consisting of surfactants (1) and a water-soluble inert substance (2) which has been evaporated until it has a dry consistency, so that the tablets are adapted for dissolving in windshield wash water of not more than 2 liters.

23. The windshield washing concentrate according to claim 22, wherein the diameter of the tablets (100)<=15 mm and their thickness<=10 mm and that the tablets (100) contain a concentrate (12) consisting of surfactants (1) and a water-soluble inert substance (2) which has been evaporated until it has a dry consistency, so that the tablets are adapted for dissolving in windshield wash water of not more than <=1 liter.

24. The windshield washing concentrate according to claim 22, wherein at least sodium bicarbonate (3a) and citric acid (3c) are contained as at least a portion of the additives.

25. The windshield washing concentrate according to claim 22, wherein a pigments (3b) is contained as a portion of the additives.

26. The windshield washing concentrate according to claim 22, wherein a fragrant substances (3c) is contained as a portion of the additives.

27. The windshield washing concentrate according to claim 19, wherein the outer contour displays a company logo or the like.

28. The windshield washing concentrate according to claim 20, wherein each pellet surface is compacted so as to be smooth by means of the applied pressure of a the matrix die.
